(19) United States
(12) Patent Application Publication
(10) Pub. No.: US 2022/0413381 A1
(43) Pub. Date: Dec. 29, 2022

(54) COLORING AGENT COMPOSITION, PHOTOSENSITIVE RESIN COMPOSITION, PHOTORESIST, COLOR FILTER, AND LIQUID CRYSTAL DISPLAY DEVICE

(71) Applicant: LG CHEM, LTD., Seoul (KR)

(72) Inventors: Dami LEE, Daejeon (KR); Youngwoong KIM, Daejeon (KR); Kyung Lim PAIK, Daejeon (KR); Ki Youl LEE, Daejeon (KR); Mihee PARK, Daejeon (KR); U Ra LEE, Daejeon (KR); Hyun Suk KIM, Daejeon (KR)

(73) Assignee: LG CHEM, LTD., Seoul (KR)

(21) Appl. No.: 17/775,130

(22) PCT Filed: Dec. 2, 2020
(86) PCT No.: PCT/KR2020/017447

§ 371 Date: May 6, 2022

(30) Foreign Application Priority Data
Dec. 2, 2019 (KR) 10-2019-0158334

(51) Int. Cl. G03F 7/00; G03F 7/028; G03F 7/032; G02B 5/22; G02F 1/1335

(52) U.S. Cl. CPC G03F 7/0007; G03F 7/028; G03F 7/032; G02B 5/223; G02F 1/133516

(57) ABSTRACT

The present invention relates to a colorant composition including a first color material and a second color material, in which the first color material and the second color material each have a transmittance of 60% or less at a wavelength of 490 nm or more and 605 nm or less, a transmittance of 90% or more at a wavelength of 470 nm or less, and a transmittance of 98% or more at a wavelength of 620 nm or more.

### TECHNICAL FIELD

This application is a 35 U.S.C. 371 National Phase Entry Application from PCT/KR2020/01017447, filed on Dec. 2, 2020, which claims priority to and the benefit of Korean Patent Application No. 10-2019-0158334 filed in the Korean Intellectual Property Office on Dec. 2, 2019, the entire contents of which are incorporated herein by reference.

The present invention relates to a colorant composition, a photosensitive resin composition, a photoresist, a color filter, and a liquid crystal display device.

### BACKGROUND OF THE INVENTION

A smooth coating film may be obtained by spin-coating a photosensitive resin composition onto a substrate, and heating and drying the photosensitive resin composition to remove a solvent.

After the coating film thus obtained is irradiated with ultraviolet rays by a negative mask for forming a desired image to cure an exposed portion, the coating film is developed by dissolving an unexposed portion in a developing solution.

By repeatedly performing the process described above in the same manner using a photosensitive resin composition, it is possible to form a coating film prepared using a photosensitive resin composition of each color as a target pixel (pattern).

There is a problem in that when the same process needs to be repeated three times to form a color filter by the above method, the process cost is increased and a dye which has high transparency, but is weak to heat, cannot be used because a heat treatment process needs to be repeated.

### BRIEF SUMMARY OF THE INVENTION

The present specification provides a colorant composition, a photosensitive resin composition, a photoresist, a color filter, and a liquid crystal display device.

An exemplary embodiment of the present specification provides a colorant composition including a first color material and a second color material, in which the first color material and the second color material each have a transmittance of 60% or less at a wavelength of 490 nm or more and 605 nm or less, a transmittance of 90% or more at a wavelength of 470 nm or less, and a transmittance of 98% or more at a wavelength of 620 nm or more.

An exemplary embodiment of the present specification provides a photosensitive resin composition including the colorant composition.

An exemplary embodiment of the present specification provides a photoresist formed using the photosensitive resin composition.

An exemplary embodiment of the present specification provides a color filter manufactured using the photoresist.

An exemplary embodiment of the present specification provides a liquid crystal display device including the color filter.

### ADVANTAGEOUS EFFECTS

When a color filter is prepared using a colorant composition according to the present specification and a photosensitive resin composition including the same, there are effects in that the transmittance is excellent and the process cost can be reduced.

Further, when a color filter is prepared using the colorant composition and a photosensitive resin composition including the same, it is possible to realize red and blue colors with one color filter.

### DETAILED DESCRIPTION OF THE INVENTION

An exemplary embodiment of the present invention provides a colorant composition including a first color material and a second color material, in which the first color material and the second color material each have a transmittance of 60% or less at a wavelength of 490 nm or more and 605 nm or less, a transmittance of 90% or more at a wavelength of 470 nm or less, and a transmittance of 98% or more at a wavelength of 620 nm or more.

When the first color material and the second color material satisfy the above-described wavelength range and transmittance range, the matching with the range of a light source that emits light is high, so that there is an effect of improving the transmittance.

In an exemplary embodiment of the present specification, the first color material and the second color material are a pigment or a dye.

The pigment or the dye is not particularly limited in type as long as the pigment or the dye satisfies the wavelength range and the transmittance range according to the present specification.

In the present specification, the pigment or the dye may be indicated as a ‘compound’.

In an exemplary embodiment of the present specification, the first color material has a maximum absorption wavelength within a range of 550 nm to 580 nm.

In an exemplary embodiment of the present specification, the first color material has a transmittance of 85% or more at a wavelength of 480 nm or less and 610 nm or more.

Specifically, the first color material shows a maximum transmittance at 680 nm or more.

In an exemplary embodiment of the present specification, the second color material has a maximum absorption wavelength within a range of 530 nm to 560 nm.

In an exemplary embodiment of the present specification, the second color material has a transmittance of 85% or more at a wavelength of 470 nm or less and 580 nm or more.

Specifically, the second color material shows a maximum transmittance at 470 nm or less.

In an exemplary embodiment of the present specification, the first color material and the second color material are a xanthene-based color material.

In an exemplary embodiment of the present specification, the first color material and the second color material each have a transmittance of 60% or less at a wavelength of 490 nm or more and 606 nm or less. Specifically, the first color material and the second color material each have a transmittance of 60% or less at a wavelength of 501 nm or more and 601 nm or less. More specifically, the first color material and the second color material each have a transmittance of 60% or less at a wavelength of 516 nm or more and 574 nm or less.

The first color material and the second color material can be adopted without limitation as long as the first color material and the second color material satisfy the above-described wavelength range and the above-described transmittance range.

In an exemplary embodiment of the present specification, the transmittance is a value measured by spin-coating the first color material, the second color material, or the colorant composition onto a base material, heat-treating the base material to form a color substrate, and then using a spectrometer (MCPD, manufactured by Otsuka Electronics Co., Ltd.) for the formed color substrate.

In an exemplary embodiment of the present specification, the base material can be used without limitation as long as the base material acts as a support. For example, the base material may be glass.

In an exemplary embodiment of the present specification, a weight ratio of the first color material:the second color material is 1:9 to 9:1. Specifically, a weight ratio of the first color material:the second color material is 3:7 to 6:4.

When the colorant composition satisfies the weight ratio range, a color filter layer capable of realizing red and blue colors can be formed by one coating.

In an exemplary embodiment of the present specification, the colorant composition further includes an additional color material in addition to the first color material and the second color material. That is, the colorant composition includes two or more color materials.

In an exemplary embodiment of the present specification, the additional color material can be applied without limitation as long as the additional color material is a color material used in the art.

In an exemplary embodiment of the present specification, the colorant composition may further include one or more of a binder resin; a leveling agent; an adhesion aid; an initiator; and a solvent.

In the present specification, when the colorant composition further includes one or more of the materials, the colorant composition may be expressed as a photosensitive resin composition. That is, when the colorant composition further includes one or more of the materials, the terms ‘colorant composition’ and ‘photosensitive resin composition’ can be used interchangeably.

In an exemplary embodiment of the present specification, the colorant composition further includes: a binder resin; a leveling agent; and a solvent.

An exemplary embodiment of the present specification provides a photosensitive resin composition including the above-described colorant composition.

In an exemplary embodiment of the present specification, the photosensitive resin composition further includes one or more of a binder resin; a leveling agent; an adhesion aid; an initiator; and a solvent.

In an exemplary embodiment of the present specification, the photosensitive resin composition further includes: a binder resin; a leveling agent; and a solvent.

In an exemplary embodiment, the photosensitive resin composition may further include a photoinitiator.

The binder resin is not particularly limited as long as the binder resin may exhibit physical properties, such as strength and developability, of a film manufactured by using the resin composition.

The binder resin may use a copolymer resin of a polyfunctional monomer which imparts mechanical strength and a monomer which imparts alkali solubility, and may further include a binder generally used in the art.

The polyfunctional monomer which imparts mechanical strength of a film may be any one or more of unsaturated carboxylic acid esters; aromatic vinyls; unsaturated ethers; unsaturated imides; and acid anhydrides.

Specific examples of the unsaturated carboxylic acid esters may be selected from the group consisting of benzyl(meth)acrylate, methyl(meth)acrylate, ethyl(meth)acrylate, butyl(meth)acrylate, dimethylaminoethyl(meth)acrylate, isobutyl(meth)acrylate, t-butyl(meth)acrylate, cyclohexyl(meth)acrylate, isobornyl(meth)acrylate, ethylhexyl(meth)acrylate, 2-phenoxyethyl(meth)acrylate, tetrahydrofurfuryl(meth)acrylate, hydroxyethyl(meth)acrylate, 2-hydroxypropyl(meth)acrylate, 2-hydroxy-3-chloropropyl(meth)acrylate, 4-hydroxybutyl(meth)acrylate, acyloctyloxy-2-hydroxypropyl(meth)acrylate, glycerol(meth)acrylate, 2-methoxyethyl(meth)acrylate, 3-methoxybutyl(meth)acrylate, ethoxydiethylene glycol(meth)acrylate, methoxytriethylene glycol(meth)acrylate, methoxytripropylene glycol(meth)acrylate, poly(ethylene glycol) methylether(meth)acrylate, phenoxydiethylene glycol(meth)acrylate, p-nonylphenoxypolyethylene glycol(meth)acrylate, p-nonylphenoxypolypropylene glycol(meth)acrylate, glycidyl(meth)acrylate, tetrafluoropropyl(meth)acrylate, 1,1,1,3,3,3-hexafluoroisopropyl (meth)acrylate, octafluoropentyl(meth)acrylate, heptadecafluorodecyl(meth)acrylate, tribromophenyl(meth)acrylate, methyl α-hydroxymethyl acrylate, ethyl α-hydroxymethyl acrylate, propyl α-hydroxymethyl acrylate, and butyl α-hydroxymethyl acrylate, but are not limited thereto.

Specific examples of the aromatic vinyls may be selected from the group consisting of styrene, α-methylstyrene, (o,m,p)-vinyl toluene, (o,m,p)-methoxy styrene, and (o,m,p)-chloro styrene, but are not limited thereto.

Specific examples of the unsaturated ethers may be selected from the group consisting of vinyl methyl ether, vinyl ethyl ether, and allyl glycidyl ether, but are not limited thereto.

Specific examples of the unsaturated imides may be selected from the group consisting of N-phenyl maleimide, N-(4-chlorophenyl) maleimide, N-(4-hydroxyphenyl) maleimide, and N-cyclohexyl maleimide, but are not limited thereto.

Examples of the acid anhydrides include anhydrous maleic acid, anhydrous methyl maleic acid, tetrahydrophthalic acid anhydride, and the like, but are not limited thereto.

The monomer which imparts alkali solubility is not particularly limited as long as the monomer includes an acid group, and it is preferred to use one or more selected from the group consisting of, for example, (meth)acrylic acid, crotonic acid, itaconic acid, maleic acid, fumaric acid, monomethyl maleic acid, 5-norbornene-2-carboxylic acid, mono-2-((meth)acryloyloxy)ethyl phthalate, mono-2-((meth)acryloyloxy)ethyl succinate, and ω-carboxy polycaprolactone mono(meth)acrylate, but the monomer is not limited thereto.

According to an exemplary embodiment of the present specification, the binder resin has an acid value of 50 to 130 KOH mg/g and a weight average molecular weight of 1,000 g/mol to 50,000 g/mol.

The leveling agent may be polymeric or non-polymeric. Specific examples of the polymeric leveling agent include polyethylene imine, polyamide amine, and a reaction product of amine and epoxide, and specific examples of the non-polymeric leveling agent include non-polymeric sulfur-containing and non-polymeric nitrogen-containing compounds, but the examples are not limited thereto, and those generally used in the art may all be used.

The adhesion aid is not particularly limited, and an adhesion aid generally used in the art may be used.

The photosensitive resin composition according to the present specification may additionally include a photoinitiator.

As the photoinitiator, one or more compounds selected from 2,4-trichloromethyl-(4′-methoxyphenyl)-6-triazine, 2,4-trichloromethyl-(4′-methoxystyryl)-6-triazine, 2,4-trichloromethyl-(fipronil)-6-triazine, 1-hydroxycyclohexyl phenyl ketone, 4-(2-hydroxyethoxy)-phenyl(2-hydroxy)propyl ketone, benzophenone, 2,4,6-trimethylaminobenzophenone, and the like may be used, but the photoinitiator is not limited thereto.

The content of the photoinitiator is preferably 0.1 to 5 wt % based on the total weight of the photosensitive resin composition, but is not limited thereto.

In the photosensitive resin composition according to the present specification, as the solvent, one or more compounds selected from methyl ethyl ketone, propylene glycol diethyl ether, propylene glycol methyl ether acetate, 3-methoxybutyl acetate, dipropylene glycol monomethyl ether, and the like may be used, but the solvent is not limited thereto.

The content of the solvent is preferably 45 wt % to 95 wt % based on the total weight of the photosensitive resin composition, but is not limited thereto.

Further, the photosensitive resin composition according to the present specification may additionally include one or more additives selected from the group consisting of a curing accelerator, a thermal polymerization inhibitor, a surfactant, a photoresist, a plasticizer, an adhesion promoter, and a filler according to the use.

Examples of the curing accelerator include one or more selected from the group consisting of 2-mercaptobenzoimidazole, 2-mercaptobenzothiazole, 2-mercaptobenzoxazole, 2,5-dimercapto-1,3,4-thiadiazole, 2-mercapto-4,6-dimethylaminopyridine, pentaerythritol tetrakis(3-mercaptopropionate), pentaerythritol tris(3-mercaptopropionate), pentaerythritol tetrakis(2-mercaptoacetate), pentaerythritol tris(2-mercaptoacetate), trimethylolpropane tris(2-mercaptoacetate), trimethylolpropane tris(3-mercaptopropionate), trimethylolethane tris(2-mercaptoacetate), and trimethylolethane tris(3-mercaptopropionate), but are not limited thereto, and may include those generally known in the art.

Examples of the thermal polymerization inhibitor include one or more selected from the group consisting of p-anisole, hydroquinone, pyrocatechol, t-butyl catechol, N-nitrosophenylhydroxyamine ammonium salt, N-nitrosophenylhydroxyamine aluminum salt, and phenothiazine, but are not limited thereto, and may include those generally known in the art.

As the surfactant, the photoresist, the plasticizer, the adhesion promoter, the filler, and the like, all the compounds, which may be included in the photosensitive resin composition in the related art, may be used.

The contents of the additives are each independently preferably 0.01 to 5 wt % based on the total weight of the photosensitive resin composition, but are not limited thereto.

Meanwhile, the photosensitive resin composition according to the present specification may be applied onto a support such as metal, paper, and a glass/plastic substrate using a roll coater, a curtain coater, a spin coater, a slot die coater, various printing methods, a deposition method, and the like. In addition, it is also possible to apply the photosensitive resin composition onto a support such as a film and then transfer the photosensitive resin composition onto another support, or apply the photosensitive resin composition onto a first support, and then transfer the photosensitive resin composition to a blanket or the like, and again transfer the photosensitive resin composition to a second support, and the application method thereof is not particularly limited.

The photosensitive resin composition is used preferably for a pigment dispersion-type photoresist for manufacturing a TFT LCD color filter, a photoresist for forming a black matrix of a TFT LCD or an organic light emitting diode, a photoresist for forming an overcoat layer, and a column spacer photoresist, but may be used for manufacturing a photocurable paint, a photocurable ink, a photocurable adhesive, a printing plate, a photoresist for a printed circuit board, other transparent photoresists, a PDP, and the like, and the use thereof is not particularly limited.

An exemplary embodiment of the present specification provides a photoresist formed using the photosensitive resin composition.

An exemplary embodiment of the present specification provides a color filter manufactured using the photosensitive resin composition.

An exemplary embodiment of the present specification provides a color filter manufactured using the photoresist.

The color filter may be manufactured by a method known in the art, except that the photosensitive resin composition according to the present specification is used.

An exemplary embodiment of the present specification provides a color substrate including the color filter.

In an exemplary embodiment of the present specification, the color substrate includes: a base material; and a color filter.

In an exemplary embodiment of the present specification, the color filter may be manufactured in the form of a film.

An exemplary embodiment of the present specification provides a liquid crystal display device including the color filter.

The liquid crystal display device according to the present specification may be manufactured using a technique in the art, except that the photosensitive resin composition of the present invention is used.

For example, after a metal film such as Cr or a black resin film is applied onto a transparent substrate, a partition wall (black matrix) is formed as a boundary other than a pixel region where a color filter is formed by performing patterning by a photolithography method, and the like.

Red, green, and blue color filters may be formed by injecting red, green, and blue tinged color filter ink compositions into the pixel regions defined by the transparent openings between the partition walls and curing the ink compositions. In this case, the above-described photosensitive resin composition may be used as the color filter ink composition.

In an exemplary embodiment of the present specification, the liquid crystal display device includes a color filter and a liquid crystal panel provided with a liquid crystal, in which the color filter includes a first color material and a second color material, and the first color material and the second color material each have a transmittance of 60% or less at a wavelength of 490 nm or more and 605 nm or less, a transmittance of 90% or more at a wavelength of 470 nm or less, and a transmittance of 98% or more at a wavelength of 620 nm or more.

Hereinafter, preferred examples for helping the understanding of the present invention will be suggested. However, the following Examples are provided for illustrating the present application, and the scope of the present specification is not limited thereby.

### PREPARATION EXAMPLES

### Preparation of Compounds A to G

In Table 1, Compound A and Compound B were obtained by performing synthesis in the same manner as Compounds 1-32 and Compound Ay, respectively, in Synthesis Example 2 of Patent JP 2016-170282, which is incorporated by reference herein.

### Synthesis Method of [Compound B]

40.5 g of a compound represented by Formula Ax and 60.5 g of 2,6-dimethylaniline were mixed under light-shielding conditions, and the mixture was stirred at 150° C. for 8 hours in 200 parts of N-methyl pyridone. The obtained reaction solution was cooled to room temperature, and then added to a mixed solution of 1,200 parts of distilled water and 75 g of 35% hydrochloric acid, the resulting mixture was stirred at room temperature for 1 hour, and then the precipitate was filtered under reduced pressure. The filtrate was put into 100 g of methanol, and the resulting mixture was refluxed at 60° C. for 16 hours, and then filtered under reduced pressure to obtain 49.0 g of a compound represented by Compound B.

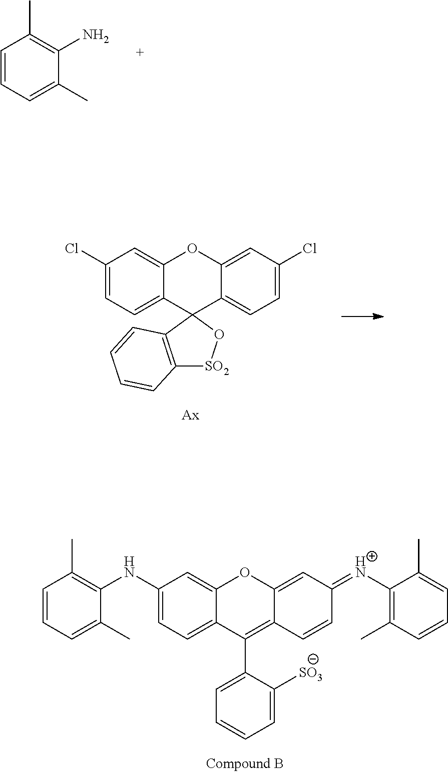

### Synthesis Method of [Compound A]

28.8 g of the compound represented by Compound B, 21.6 g of 1-bromopropane and 24.2 g of potassium carbonate were added to 144 g of N-methyl pyridone, and the resulting mixture was stirred at 90° C. for 4 hours. The obtained reaction solution was cooled to room temperature, then concentrated, and added to 560 g of distilled water, the resulting mixture was stirred at 10 to 15° C., and then the precipitate was filtered under reduced pressure. The filtered precipitate was washed with 1,000 g of distilled water, and then dried under reduced pressure to obtain 30 g of Compound A.

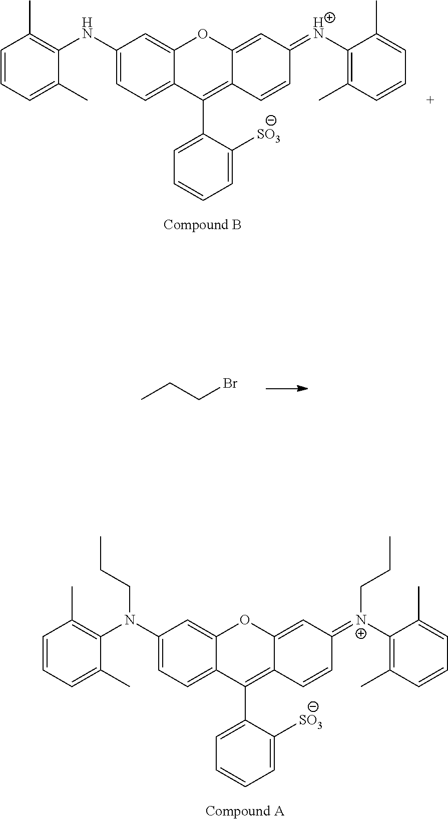

Compound C and Compound D were obtained by performing synthesis in the same manner as Chemical Formula 3 and Chemical Formula 5, respectively, in Patent KR 2015-0055895, which is incorporated by reference herein.

### Synthesis Method of [Compound C]

200 g of dichloromethane was added to 10.1 g of rhodamine B (Ay) and 1.0 g of DMF and dissolved under stirring. Thereafter, 7.50 g of thionyl chloride was added thereto, and the resulting mixture was reacted for 1 hour by increasing the temperature to 40° C. Distillation under reduced pressure was performed to remove dichloromethane and residual thionyl chloride, thereby synthesizing an acid chloride. After 4.2 g of 4-hydroxypiperidine and 4.2 g of triethylamine were dissolved in 200.0 g of dichloromethane in a separate reactor, the resulting solution was cooled to 0° C. or less.

The acid chloride obtained above was dissolved in 100 g of dichloromethane, and the resulting solution was added dropwise to the reactor for 2 hours while maintaining the reactor temperature at 0° C. or less. After the reaction was completed, triethylamine was removed by adding distilled water thereto for washing, and then the product was purified to obtain 9.3 g of [Chemical Formula I].

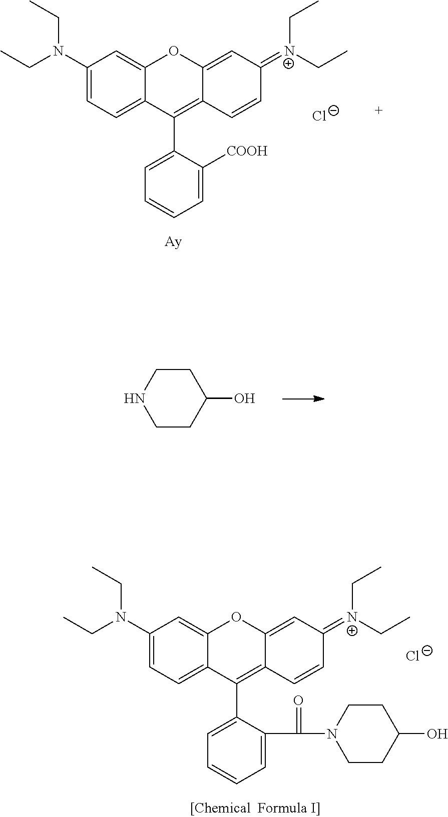

70.0 g of dichloromethane was added to 9.0 g of the compound of [Chemical Formula I] and 2.4 g of triethylamine and dissolved by stirring. Thereafter, after 3.7 g of methacrylic acid anhydride was added thereto, the temperature was increased to 40° C. and maintained. After the reaction was terminated, distilled water was added thereto, and the resulting mixture was stirred and washed. After layers were separated, the organic layer was concentrated under reduced pressure and purified to obtain 6.9 g of a compound of [Chemical Formula II].

90.0 g of dichloromethane was added to 6.9 g of the compound of [Chemical formula II] and dissolved by stirring. 4.1 g of lithium nonafluorobutanesulfonate was dissolved in a 20% aqueous solution, the resulting solution was added thereto, and then the resulting mixture was stirred at room temperature for 1 hour. Layers were separated, and the organic layer was washed with water, concentrated under reduced pressure, and then purified to obtain 8.3 g of [Compound C].

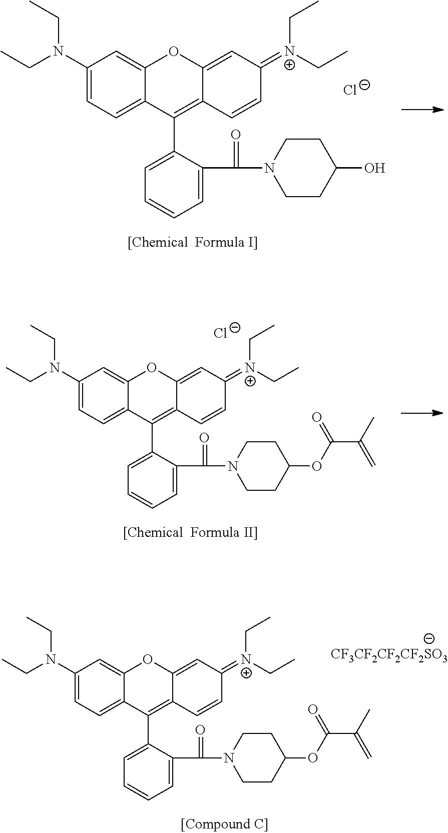

### Synthesis Method of [Compound D]

200.0 g of dichloromethane was added to 10.1 g of rhodamine B (Ay) and 1.0 g of DMF and dissolved under stirring. Thereafter, 7.5 g of thionyl chloride was added thereto, and the resulting mixture was reacted for 1 hour by increasing the temperature to 40° C. Distillation under reduced pressure was performed to remove dichloromethane and residual thionyl chloride, thereby synthesizing an acid chloride. After 5.5 g of 1-(2-hydroxyethyl)piperazine and 4.2 g of triethylamine were dissolved in 200.0 g of dichloromethane in a separate reactor, the resulting solution was cooled to 0° C. or less.

The acid chloride obtained above was dissolved in 100 g of dichloromethane, and the resulting solution was added dropwise to the reactor for 2 hours while maintaining the reactor temperature at 0° C. or less. After the reaction was completed, triethylamine was removed by adding water thereto for washing, and then the product was purified to obtain 9.2 g of [Chemical Formula III].

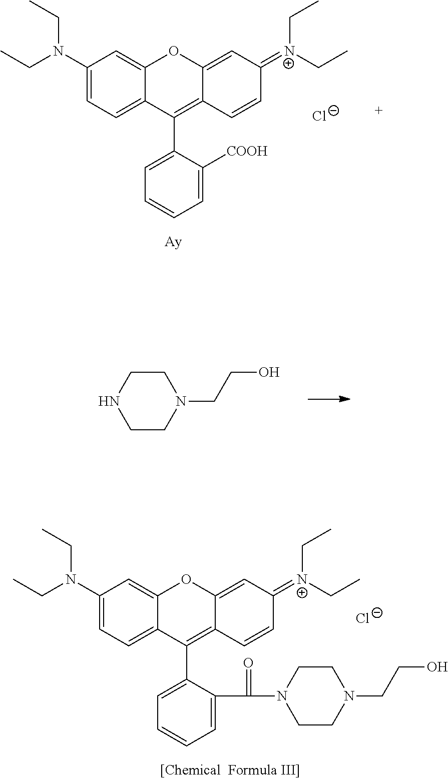

70.0 g of dichloromethane was added to 7.1 g of the compound of [Chemical Formula III] and 2.4 g of triethylamine and dissolved by stirring. Thereafter, after 3.7 g of methacrylic acid anhydride was added thereto, the temperature was increased to 40° C. and maintained. After the reaction was terminated, water was added thereto, and the resulting mixture was stirred and washed. After layers were separated, the organic layer was concentrated under reduced pressure and purified to obtain 6.6 g of a compound of [Chemical Formula IV].

90.0 g of dichloromethane was added to 6.6 g of the compound of [Chemical Formula IV] and dissolved by stirring. 3.2 g of lithium bis(trifluoromethane)sulfonimide was dissolved in a 20% aqueous solution, the resulting solution was added thereto, and then the resulting mixture was stirred at room temperature for 1 hour. Layers were separated, and the organic layer was washed with distilled water, concentrated under reduced pressure, and then purified to obtain 7.9 g of [Compound D].

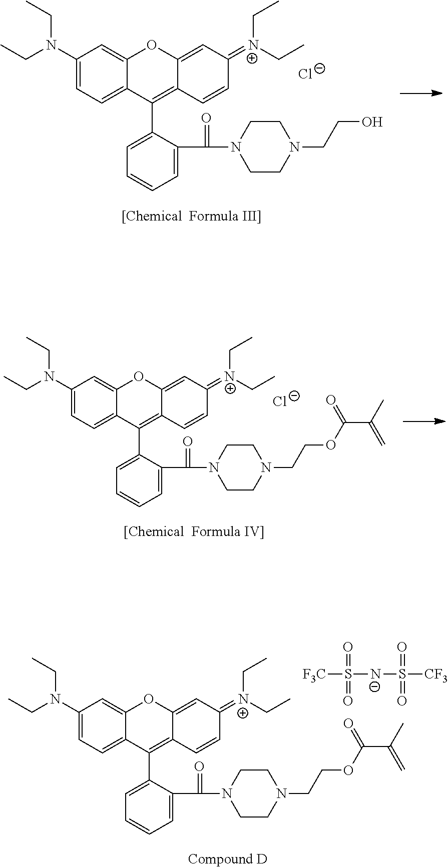

Compound E was obtained by performing synthesis in the same manner as Formula (101) in Patent JP 2014-056214, which is incorporated by reference herein.

### Synthesis of [Compound E]

30 g of DMF, 6.8 g of benzyl bromide, 3.0 g of potassium carbonate, 4.3 g of 1,8-diazabicyclo [5,4,0] undec-7-ene and 9.6 g of rhodamine B (Ay) were stirred at 90° C. for 6 hours. After the reaction solution was filtered, distilled water was added to the filtrate to make 500 g, 5.0 g of zinc chloride and 10.0 g of sodium chloride were added dropwise thereto, and the resulting mixture was stirred for 1 hour. The precipitate was filtered under reduced pressure and washed with distilled water to obtain 8.0 g of [Compound E].

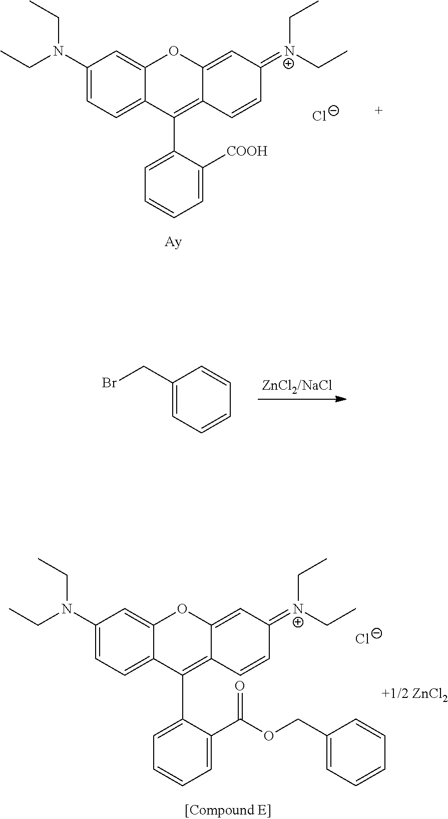

Compound F and Compound G were obtained by performing synthesis in the same manner as Compound A-1 and Compound A-2, respectively, in Patent WO 2019-082593, which is incorporated by reference herein.

### Synthesis of [Compound F]

40.0 g of Ax, 28.9 g of diethylamine, and 400 g of n-methylpyrrolidone (NMP) were put into a reactor, and the resulting mixture was stirred at 120° C. for 5 hours. 1,200 g of distilled water and 75 g of 35% hydrochloric acid were added to the mixed solution, and the resulting mixture was stirred at room temperature for 1 hour. The aqueous layer was separated by adding 100 g of sodium chloride thereto, and then dissolved by adding 500 g of chloroform thereto, and the organic layer was separated by adding saturated brine thereto. The separated organic layer was allowed to pass through sodium sulfate and concentrated under reduced pressure. Hexane was added to the concentrate, the resulting mixture was stirred at 40° C. for 2 hours, and then the precipitated solid was filtered under reduced pressure to obtain 42.5 g of [Chemical Formula V].

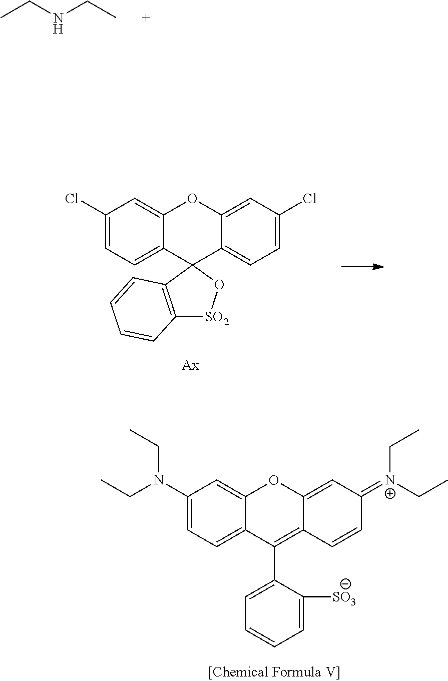

10.0 g of [Chemical formula V], 1.85 g of N,N-dimethylformamide, 100 g of chloroform, and 8.04 g of thionyl chloride were put into a reactor under nitrogen atmosphere, and the resulting mixture was stirred at 90° C. for 2 hours. After 100 g of chloroform was added to the concentrated reaction solution and dissolved, 1.24 g of diethylamine and 3.42 g of triethylamine were added thereto, and the resulting mixture was reacted at 50° C. for 4 hours. The reaction solution was washed with saturated brine, and the organic layer was separated and allowed to pass through sodium sulfate to remove water. A purple oil dried under reduced pressure was purified to obtain 4.8 g of [Chemical Formula VI].

6.3 g of [Chemical Formula VI] and 120 g of distilled water put into a reactor, and the resulting mixture was reversibly dissolved at about 70° C. A mixed solution of 3.0 g of a sodium salt of Az and 30 g of distilled water was gradually added dropwise to the solution. After dropwise addition, the resulting mixture was stirred at 80° C. for 1 hour, cooled to room temperature, and washed several times with distilled water. The solid was filtered under reduced pressure, recrystallized with ethanol and hexane, and dried under reduced pressure to obtain 4.9 g of [Compound F].

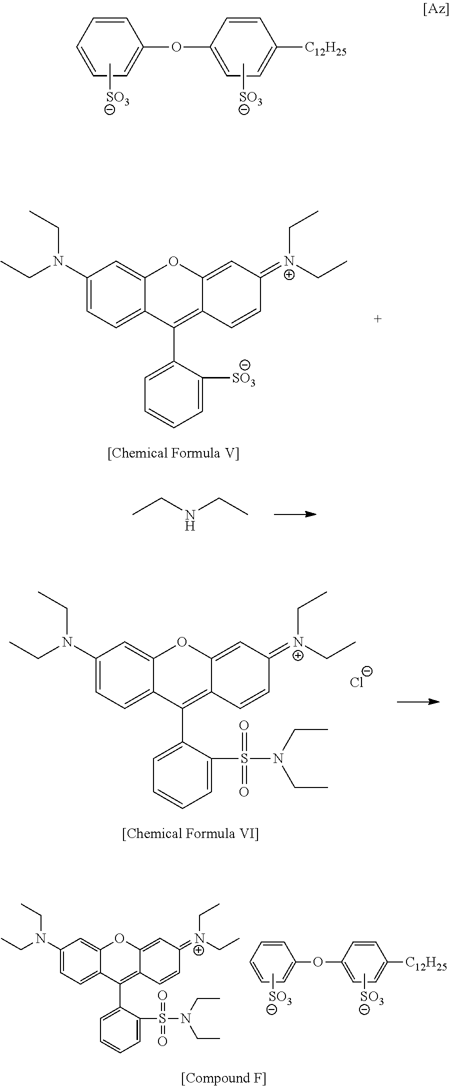

### Synthesis of [Compound G]

5.4 g of [Compound G] was obtained by performing synthesis in the same manner as in the process of synthesizing [Compound V], except that diethylamine was changed to 51.0 g of dibutylamine.

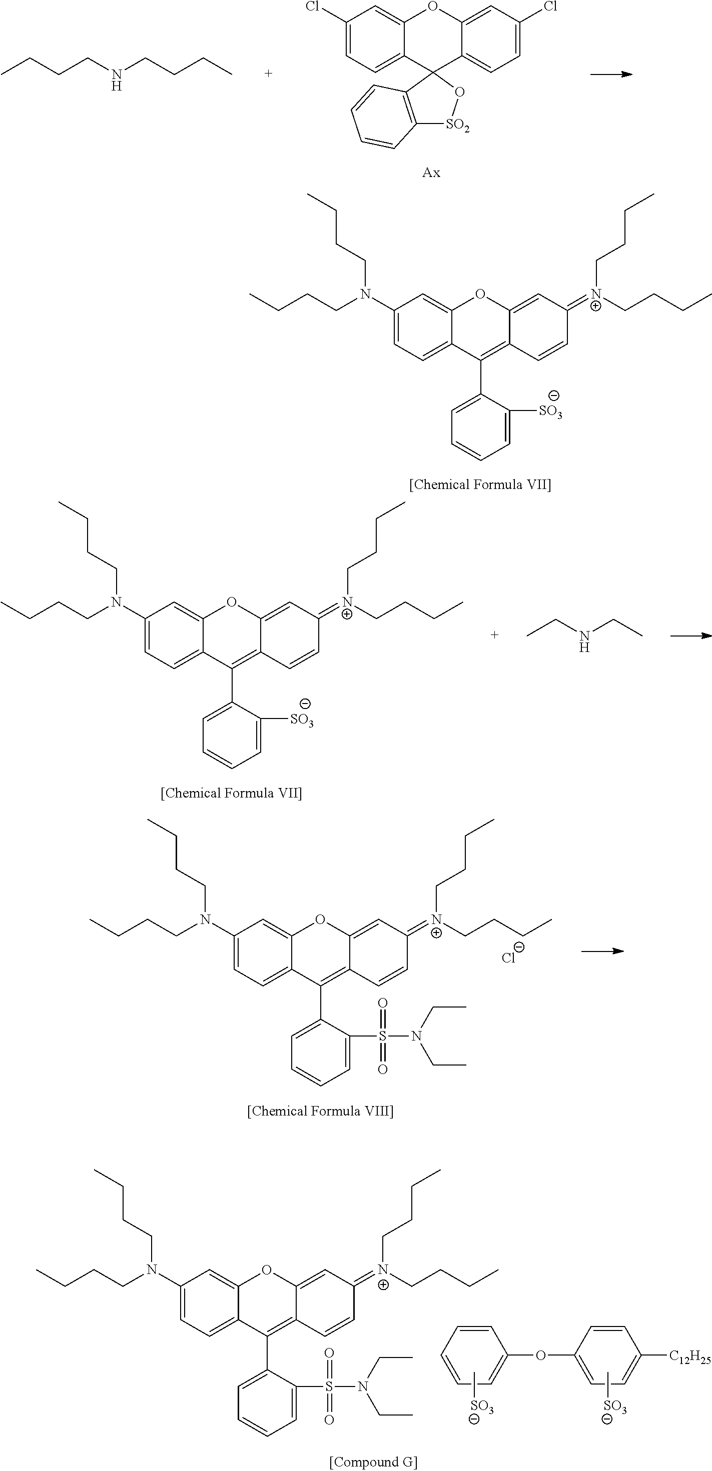

### Preparation of Compound Compositions

### Compound Composition 1

Compound Composition 1 was prepared by mixing 0.4 part by weight of Compound A, 79.95 parts by weight of Binder Resin A, 0.68 part by weight of Leveling Agent F-554(Megaface F-554, DIC), and 18.97 parts by weight of propylene glycol methyl ether acetate based on 100 parts by weight of the total weight of the compound compositions.

Binder Resin A is a copolymer having a mass ratio of benzyl methacrylate: N-phenylmaleimide:styrene:methacrylic acid=55:9:11:25.

### Compound Compositions 2 to 9

Compound Compositions 2 to 9 were prepared in the same manner as in the preparation of Compound Composition 1, except that in the preparation of Compound Composition 1, the compounds in the following Table 1 were used instead of Compound A.

The structures of Compounds A to G, R177(Dispersion with R177 18% solids, SANYO), and B15:6(B15:6 dispersion with 12% solids, SANYO) described in the following Table 1 are as follows.

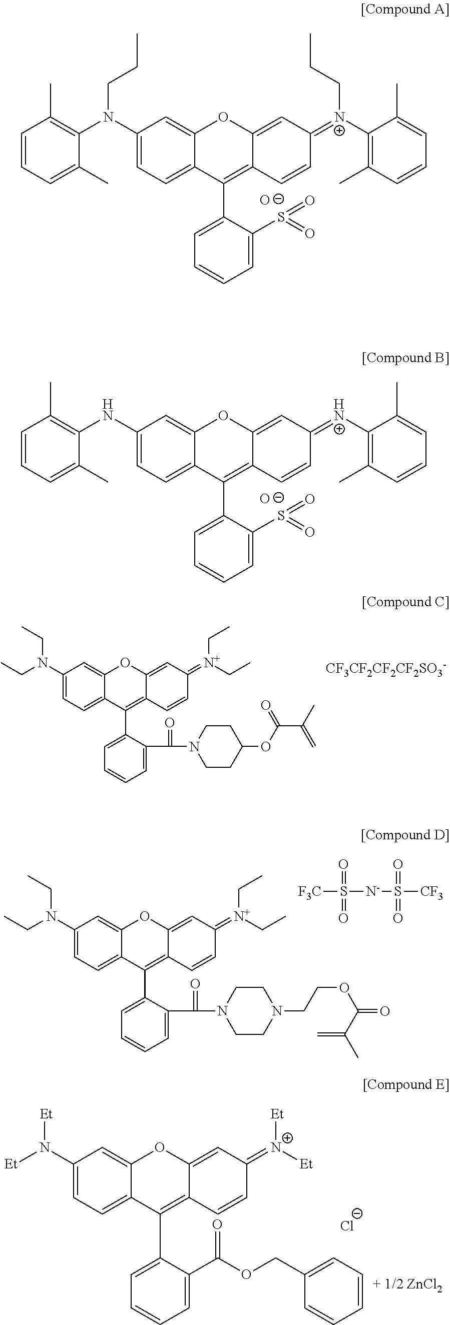

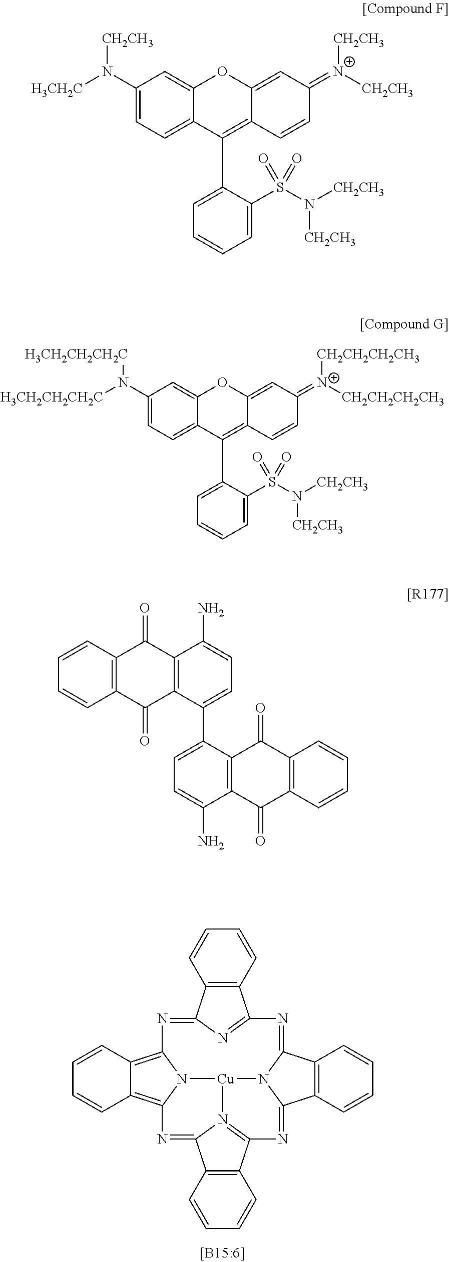

### Manufacture of Substrate

The prepared Compound Compositions 1 to 9 were spin-coated onto glass (5 cm×5 cm), respectively, and pre-heat-treated (pre bake) at 100° C. for 100 seconds to manufacture substrates.

### Evaluation of Transmittance

The absorption spectrum of the manufactured substrate in a wavelength range of 380 nm to 780 nm was measured using a spectrometer (MCPD, manufactured by Otsuka Electronics Co., Ltd.), and is shown in the following Table 1.

TABLE 1

| | | λ* @ | λ** @ | T @ | T @ | |
|---|---|---|---|---|---|---|
| | Used | T = 60% | T = 60% | λ = 470 nm | λ = 620 nm | |
| | compound | (nm) | (nm) | (%) | (%) | Remark |
| Compound | Compound A | 501 | 574 | 90.5 | 98.9 | Applicable |
| Composition 1 | | | | | | |
| Compound | Compound B | 476 | 570 | 69.0 | 97.3 | Not |
| Composition 2 | | | | | | applicable |
| Compound | Compound C | 513 | 593 | 93.7 | 99.0 | Applicable |
| Composition 3 | | | | | | |
| Compound | Compound D | 516 | 601 | 94.7 | 98.6 | Applicable |
| Composition 4 | | | | | | |
| Compound | Compound E | 508 | 591 | 92.2 | 98.2 | Applicable |
| Composition 5 | | | | | | |
| Compound | Compound F | 529 | 605 | 94.0 | 95.8 | Not |
| Composition 6 | | | | | | applicable |
| Compound | Compound G | 509 | 606 | 80.6 | 94.9 | Not |
| Composition 7 | | | | | | applicable |
| Compound | R177 | — | 549 | 30.3 | 96.5 | Not |
| Composition 8 | | | | | | applicable |
| Compound | B15:6 | 505 | 585 | 97.9 | 66.8 | Not |
| Composition 9 | | | | | | applicable |

In Table 1, ‘applicable’ means that the compound composition can act as red and blue color filters intended in the present specification, and ‘not applicable’ means that the compound composition cannot act as red and blue color filters intended in the present specification.

In Table 1, λ* @T=60% means the wavelength of the left slope (value of the shorter wavelength of the wavelengths at a transmittance of 60%) at a transmittance of 60%,

λ** @T=60% means the wavelength of the right slope (value of the longer wavelength of the wavelengths at a transmittance of 60%) at a transmittance of 60%,

T @λ=470 nm means the transmittance at a wavelength of 470 nm, and

T @λ=620 nm means the transmittance at a wavelength of 620 nm.

In Table 1, all wavelengths between λ* @T=60% and λ** @T=60% show a transmittance of 60% or less.

### Preparation of Colorant Composition

### Example 1

A colorant composition of Example 1 was prepared by mixing 33 parts by weight of Compound Composition 1 and 67 parts by weight of Compound Composition 3 based on 100 parts by weight of the total weight of the colorant composition.

### Example 2 and 3 and Comparative Examples 1 to 5

Colorant compositions of Examples 2 and 3 and Comparative Examples 1 to 5 were prepared in the same manner as in Example 1, except that in Example 1, the compound compositions in the following Table 2 were used instead of Compound Compositions 1 and 3.

TABLE 2

| | Compar- | Compar- | | | | Compar- | Compar- | Compar- |
|---|---|---|---|---|---|---|---|---|
| | ative | ative | | | | ative | ative | ative |
| | Example | Example | Example | Example | Example | Example | Example | Example |
| | 1 | 2 | 1 | 2 | 3 | 3 | 4 | 5 |
| Com- | R177 | B15:6 | Com- | Com- | Com- | Com- | Com- | Com- |
| pound l | (100) | (100) | pound | pound | pound | pound | pound | pound |
| (parts | | | Compo- | Compo- | Compo- | Compo- | Compo- | Compo- |
| by | | | sition 1 | sition 1 | sition 1 | sition 1 | sition 2 | sition 1 |
| weight) | | | (33) | (65) | (40) | (72) | (11) | (66) |
| Com- | — | — | Com- | Com- | Com- | Com- | Com- | Com- |
| pound 2 | | | pound | pound | pound | pound | pound | pound |
| (parts | | | Compo- | Compo- | Compo- | Compo- | Compo- | Compo- |
| by | | | istion 3 | sition 4 | sition 5 | sition 5 | sition 3 | sition 6 |
| weight) | | | (67) | (35) | (60) | (28) | (89) | (34) |

### Manufacture of Color Filter

The prepared colorant composition was spin-coated onto glass (5 cm×5 cm), pre-heat-treated (pre bake) at 100° C. for 100 seconds, and then post-heat-treated (post bake) at 230° C. for 20 minutes to manufacture a substrate.

### Evaluation of Transmittance

The absorption spectrum of the post-heat-treated (post bake once) substrate was measured in a wavelength range of 380 nm to 780 nm using a spectrometer (MCPD, manufactured by Otsuka Electronics Co., Ltd.), and is shown in the following Table 3.

In the following Table 3, for the transmittance, after each transmittance is measured as a reference when 100% of light with a wavelength of 380 nm to 780 nm has passed, each transmittance value is shown based on a value obtained by converting the transmittance of Example 3 to 100.

TABLE 3

| | Used compound | | | |
|---|---|---|---|---|
| | Compound 1 (parts | Compound 2 (parts | | |
| | by weight) | by weight) | Transmittance | Remark |
| Example 1 | Compound A (33) | Compound C (67) | 100.2 | |
| Example 2 | Compound A (65) | Compound D (35) | 100.7 | |
| Example 3 | Compound A (40) | Compound E (60) | 100.0 | |
| Comparative | R177 (100) | — | X | Impossible to |
| Example 1 | | | | realize Blue |
| Comparative | B15:6 (100) | — | X | Impossible to |
| Example 2 | | | | realize Red |
| Comparative | Compound A (72) | Compound F (28) | 92.4 | — |
| Example 3 | | | | |
| Comparative | Compound B (11) | Compound C (89) | 98.9 | — |
| Example 4 | | | | |
| Comparative | Compound A (66) | Compound G (34) | 83.2 | — |
| Example 5 | | | | |

In Table 3, the higher transmittance value means the higher transmittance. From Table 3, it can be confirmed that Examples 1 to 3 have higher transmittances than Comparative Examples 1 to 5. Further, it can be confirmed that Comparative Example 1 cannot realize a blue color material, and Comparative Example 2 cannot realize a red color material.

As a result, it can be confirmed that since the colorant composition according to the present specification and the photosensitive resin composition including the same can simultaneously express a red color material and a blue color material while having excellent transmittance, thereby reducing costs when a color filter is manufactured.

1. A colorant composition comprising a first color material and a second color material,
wherein the first color material and the second color material each have a transmittance of 60% or less at a wavelength of 490 mm nm or more and 605 nm or less, a transmittance of 90% or more at a wavelength of 470 nm or less, and a transmittance of 98% or more at a wavelength of 620 nm or more.

2. The colorant composition of claim 1, wherein the first color material and the second color material are a pigment or a dye.

3. The colorant composition of claim 1, wherein the first color material has a maximum absorption wavelength within a range of 550 nm to 580 nm.

4. The colorant composition of claim 1, wherein the first color material further has a transmittance of 85% or more at a wavelength of 480 nm or less and 610 nm or more.

5. The colorant composition of claim 1, wherein the second color material has a maximum absorption wavelength within a range of 530 nm to 560 nm.

6. The colorant composition of claim 1, wherein the second color material further has a transmittance of 85% or more at a wavelength of 470 nm or less and 580 nm or more.

7. The colorant composition of claim 1, wherein the first color material and the second material are a xanthene-based color material.

8. The colorant composition of claim 1, wherein a weight ratio of the first color material : the second color material is 1:9 to 9:1.

9. A photosensitive resin composition comprising the colorant composition of claim 1.

10. The photosensitive resin composition of claim 9, further comprising one or more of:
a binder resin;
a leveling agent;
an adhesion aid;
an initiator; and
a solvent.

11. A photoresist formed from the photosensitive resin composition of claim 9.

12. A color filter formed from the photoresist of claim 11.

13. A liquid crystal display device comprising the color filter of claim 12.
